(19) United States
(12) Patent Application Publication
(10) Pub. No.: US 2025/0157781 A1
(43) Pub. Date: May 15, 2025

(54) METHOD FOR OPERATING A PARTICLE BEAM APPARATUS, COMPUTER PROGRAM PRODUCT AND PARTICLE BEAM APPARATUS FOR CARRYING OUT THE METHOD

(71) Applicant: Carl Zeiss Microscopy GmbH, Jena (DE)

(72) Inventors: Bjoern Gamm, Koenigsbronn (DE); Ken Lagarec, Ottawa (CA); Michael W. Phaneuf, Ottawa (CA); Pascal Maria Anger, Aalen (DE)

(73) Assignee: Carl Zeiss Microscopy GmbH, Jena (DE)

(21) Appl. No.: 18/942,896

(22) Filed: Nov. 11, 2024

(30) Foreign Application Priority Data
Nov. 14, 2023 (DE) 102023131607.9

(51) Int. Cl. H01J 37/147

(52) U.S. Cl. CPC H01J 37/1474

(57) ABSTRACT

Operating a particle beam apparatus for imaging, analyzing and/or processing an object includes guiding a particle beam using a first guiding device and a second guiding device in such a way that the particle beam is guided to first positions on a surface of the object. The first positions are arranged along a first geometrical shape on the object. The particle beam is also guided to second positions on the surface of the object using the first guiding device and the second guiding device. The second positions are arranged along a second geometrical shape on the object. Guiding the particle beam along the first geometrical shape and/or along the second geometrical shape is faster in time than guiding the particle beam from the first geometrical shape to the second geometrical shape.

### TECHNICAL FIELD

This application relates to operating a particle beam apparatus for imaging, analyzing and/or processing an object.

### BACKGROUND

An electron beam apparatus, in particular a scanning electron microscope (hereinafter also referred to as SEM) and/or a transmission electron microscope (hereinafter also referred to as TEM), is used to examine objects (hereinafter also referred to as samples) in order to obtain knowledge regarding their properties and behavior under certain conditions.

In an SEM, an electron beam (hereinafter also referred to as primary electron beam) is generated using a beam generator and is focused onto an object to be examined using a beam guiding system. The primary electron beam is guided over a surface of the object to be examined using a deflection device in the form of a scanning device. The electrons of the primary electron beam interact with the object to be examined. As a result of the interaction, electrons are emitted from the object (so-called secondary electrons) and electrons of the primary electron beam are scattered back (so-called backscattered electrons), for example. The secondary electrons and the backscattered electrons are detected and used for imaging. Thus, an image of the object to be examined is obtained. Furthermore, the interaction generates interaction radiation, for example X-rays or cathodoluminescence light, which is detected by a detector for analysis of the object and which is subsequently evaluated.

In a TEM, a primary electron beam is generated using a beam generator and is guided onto an object to be examined using a beam guidance system. The primary electron beam passes through the object to be examined. When the primary electron beam passes through the object to be examined, the electrons of the primary electron beam interact with the material of the object to be examined. The electrons passing through the object to be examined are imaged on a luminescent screen or on a detector (for example, a camera) by a system that includes an objective lens and a projective lens. The imaging can also be done in the scan mode of a TEM. Such a TEM is usually referred to as a STEM. In addition, it may be provided to detect electrons backscattered from the object to be examined and/or secondary electrons emitted from the object to be examined for imaging the object to be examined using another detector.

It is known to combine the function of an STEM and an SEM in a single particle beam apparatus. Thus, with this particle beam apparatus, analysis and imaging of objects are possible using an SEM function and/or an STEM function.

Furthermore, a particle beam apparatus having an ion beam column is known. Ions are generated using an ion beam generator arranged in the ion beam column. The ions are used for processing an object. For example, during processing, material of the object is ablated from the object or material is applied to the object, in particular with the supply of a gas. Additionally or alternatively, the ions are used for imaging.

Furthermore, a combination apparatus is known, which combination apparatus is used for imaging, analyzing and/or processing an object. The combination apparatus is configured to guide both electrons and ions onto an object to be examined. For example, it is known to additionally equip an SEM with an ion beam column. Using an ion beam generator arranged in the ion beam column, ions are generated which are used for processing the object (for example, ablating material from the object or applying material to the object) or also for imaging the object. For this purpose, the ions are scanned over the object using a deflection device in the form of a scanning device. The SEM is used, in particular, for observing the processing, but also for further examination (imaging and/or analysis) of the processed or unprocessed object.

A particle beam apparatus may be used to image an object with a high spatial resolution. This may be achieved by using a primary electron beam having a very small diameter in the plane of the object. Furthermore, the higher the electrons of the primary electron beam are first accelerated in the particle beam apparatus and are decelerated to a desired energy (hereinafter referred to as landing energy) at the end in the objective lens or in the region of the objective lens, the better the spatial resolution may become. For example, the electrons of the primary electron beam are accelerated with an accelerating voltage of 2 kV to 30 kV and are guided through an electron beam column of the particle beam apparatus. In the region between the objective lens and the object, the electrons of the primary electron beam are decelerated to the desired landing energy with which the electrons impinge on the object. The landing energy of the electrons of the primary electron beam is, for example, in the range of 10 eV to 30 keV.

It is known to provide a particle beam apparatus with a scanning system for guiding a particle beam (for example, the primary electron beam or an ion beam) over an object. For example, the scanning system is configured as a deflection system. The deflection system may have a first deflection device and a second deflection device, the first deflection device and the second deflection device being arranged one after each other along an optical axis of the particle beam apparatus. The position of a virtual pivot point of the particle beam may be shifted along the optical axis of the particle beam apparatus by combining the deflections of the particle beam using the first deflection device and the second deflection device. The deflection of the particle beam appears to be virtually generated by a tilt about the virtual pivot point.

A method is known from the prior art, which method is used for imaging defects in crystalline materials. The method is known as Electron Channeling Contrast Imaging (hereinafter also referred to as ECCI). It is based on the effects of electron channeling and diffraction that are generated when a primary electron beam passes through a crystalline lattice of an object. Depending on the direction of the primary electron beam with respect to the crystalline lattice, the density of backscattered electrons scattered from the object changes. The crystalline lattice defects can thus be monitored by capturing the image generated by the backscattered electrons, as the impinging primary electron beam is scanned over the object. The density of the backscattered electrons is at its minimum for the given primary electron beam direction, when one set of the lattice planes is close to the Bragg condition. In this case, most of the electrons channel through the crystalline lattice.

ECCI may be combined with a further method known from the prior art, which further known method is known as Rocking Beam. The further known method pro-vides for rocking the primary electron beam over a certain angular range and provides for guiding the incident primary electron beam to a single position on the surface of the object. The further known method provides for using a two-stage-deflection beam system. The primary electron beam is deflected away from the optical axis of the particle beam apparatus by a first deflection device (also known as first guiding device) and synchronously deflected back to the optical axis by a second deflection device (also known as second guiding device). The primary electron beam is illuminated at the same position of the object using an objective lens. The further known method is carried out over a certain angular range. The further known method may be also described as follows. The primary electron beam is guided to a specific position of a scanning area on the surface of the object using (i) a first guiding device provided for guiding the primary electron beam and (ii) a second guiding device provided for guiding the primary electron beam. As viewed from the beam generator in the direction of the object, the first guiding device is arranged first, followed by the second guiding device. The first guiding device guides the primary electron beam away from the optical axis at a first angle with respect to the optical axis. The second guiding device guides the primary electron beam in the direction of the optical axis at a second angle with respect to the optical axis. The first angle and the second angle may be identical. The first angle passes through a first predeterminable range of values and the second angle passes through a second predeterminable range of values when the primary electron beam is guided to the position of the scanning area.

Reference is made to DE 11 2016 005 577 B4 and US 2020/0013581 A1 with respect to the prior art.

### SUMMARY OF THE INVENTION

Using an objective lens in a particle beam device may cause aberrations, in particular spherical aberrations, which aberrations may cause distortion. The distortion provides for unwanted deflections of the particle beam.

Therefore, the system described herein is based on the object to provide a method, a computer program product and a particle beam apparatus for carrying out the method, with which unwanted deflections of the particle beam generated by aberrations are reduced or avoided.

The method according to the system described herein is used for operating a particle beam apparatus for imaging, analyzing and/or processing an object. The particle beam apparatus includes at least one beam generator for generating a particle beam with charged particles. For example, the charged particles are electrons or ions. Furthermore, the particle beam apparatus may include an objective lens for focusing the particle beam onto the object.

The method according to the system described herein includes guiding the particle beam to the object. In particular, the particle beam is guided away from an optical axis of the particle beam apparatus with a first angle with respect to the optical axis using a first guiding device. Moreover, the method according to the system described herein includes guiding the particle beam using a second guiding device, where the particle beam is guided to the optical axis with a second angle with respect to the optical axis in such a way that the particle beam is guided to first positions on a surface of the object. The first positions are arranged along a first geometrical shape on the surface of the object. The first geometrical shape may be any geometrical shape. Embodiments of the first geometrical shape are discussed further below. The first guiding device may be a first deflection device, for example a first magnetic and/or electrostatic deflection device. The second guiding device may be a second deflection device, for example a second magnetic and/or electrostatic deflection device.

The method according to the system described herein also includes guiding the particle beam away from the optical axis with a third angle with respect to the optical axis using the first guiding device. Moreover, the method according to the system described herein includes guiding the particle beam using the second guiding device, where the particle beam is guided to the optical axis with a fourth angle with respect to the optical axis in such a way that the particle beam is guided to second positions on the surface of the object. The second positions are arranged along a second geometrical shape on the surface of the object. The second geometrical shape may be any geometrical shape. Embodiments of the second geometrical shape are discussed further below.

The method according to the system described herein provides a first guiding signal for guiding the particle beam using a control device of the particle beam apparatus. The first guiding signal is supplied to the first guiding device by the control device using a first signal connection between the control device and the first guiding device. The first signal connection may be a physical connection, for example a connection line, and/or a wireless connection, for example a radio communication system and/or a wireless local area network.

The method according to the system described herein also provides a second guiding signal for guiding the particle beam using the control device of the particle beam apparatus. The second guiding signal is supplied to the second guiding device by the control device using a second signal connection between the control device and the second guiding device. The second signal connection may be a physical connection, for example a connection line, and/or a wireless connection, for example a radio communication system and/or a wireless local area network.

The method according to the system described herein also includes providing the first guiding signal and the second guiding signal in dependence on a first distance of a center point being arranged on the surface of the object to the first geometrical shape. The first guiding signal and the second guiding signal are used for guiding the particle beam along the first geometrical shape. The first distance may be a distance of the center point to one of the first positions being arranged on the first geometrical shape. For example, the distance may be the shortest distance of all distances of the center point to the first positions being arranged on the first geometrical shape.

Furthermore, the method according to the system described herein includes providing the first guiding signal and the second guiding signal in dependence on a second distance of the center point being arranged on the surface of the object to the second geometrical shape. The first guiding signal and the second guiding signal are used for guiding the particle beam along the second geometrical shape. The second distance may be a distance of the center point to one of the second positions being arranged on the second geometrical shape. For example, the distance may be the shortest distance of all distances of the center point to the second positions being arranged on the second geometrical shape.

According to the system described herein, guiding the particle beam along the first geometrical shape and/or along the second geometrical shape is faster in time than guiding the particle beam from the first geometrical shape to the second geometrical shape.

It has been found that the method according to the system described herein reduces or avoids unwanted deflections of the particle beam generated by aberrations, in particular aberrations generated by an objective lens of the particle beam. The aberrations may be spherical aberrations. The system described herein provides the possibility to adjust the first guiding signal and the second guiding signal, using the control device, in such a way to compensate for the unwanted deflections occurred to the aberrations. For example, the first guiding signal and the second guiding signal are adjusted depending on the first distance and the second distance. Embodiments for adjusting the first guiding signal and the second guiding signal are discussed further below.

An embodiment of the method according to the system described herein additionally or alternatively includes at least one of the following: (i) using a circular shape as the first geometrical shape; (ii) using a circular shape as the second geometrical shape; (iii) using a first circle as the first geometrical shape; and (iv) using a second circle as the second geometrical shape. It is explicitly stated that the invention is not limited to these geometrical shapes. Rather, any geometrical shape may be used which is suitable for the invention.

The first geometrical shape, in particular a first circular shape and/or a first circle, may be determined by the center point and by a first radius extending from the center point along the surface of the object. The second geometrical shape, in particular a second circular shape and/or second circle, may be determined by the center point and by a second radius extending from the center point along the surface of the object. A further embodiment of the method according to the system described herein additionally or alternatively includes (i) providing the first guiding signal and the second guiding signal in dependence on the first radius for guiding the particle beam along the first geometrical shape, and (ii) providing the first guiding signal and the second guiding signal in dependence on the second radius for guiding the particle beam along the second geometrical shape.

As mentioned above, the first geometrical shape and the second geometrical shape may be any geometrical shape. Therefore, a further embodiment of the method according to the system described herein additionally or alternatively includes (i) using a first polygon as the first geometrical shape; and (ii) using a second polygon as the second geometrical shape. For example, the first geometrical shape may be a triangle or a square. Furthermore, the second geometrical shape may be a triangle or a square. As mentioned above, the invention is not limited to these geometrical shapes. Rather, any geometrical shape may be used which is suitable for the invention.

Another embodiment of the method according to the system described herein additionally or alternatively provides for the first distance being smaller than the second distance. Moreover, the method according to the system described herein includes (i) providing, by the control device, the first guiding signal with a first gain factor of a first amplifier, and (ii) providing, by the control device, the second guiding signal with a second gain factor of a second amplifier. The ratio of the first gain factor to the second gain factor is higher when guiding the particle beam along the second geometrical shape than when guiding the particle beam along the first geometrical shape.

The aforementioned gain factors are selected in dependence on the distances. As mentioned above, the first guiding signal and the second guiding signal are provided by the control device. The control device may include or may be connected to an amplifier for providing the first guiding signal and the second guiding signal. The amplifier is configured to increase or decrease the first guiding signal using the first gain factor and/or the second guiding signal using the second gain factor. Additionally or alternatively, the control device may include or may be connected to the first amplifier for providing the first guiding signal. Furthermore, the control device may include or may be connected to the second amplifier for providing the second guiding signal. The first amplifier is configured to increase or decrease the first guiding signal using the first gain factor. Moreover, the second amplifier is configured to increase or decrease the second guiding signal using the second gain factor.

A further embodiment of the method according to the system described herein additionally or alternatively provides for using the first guiding signal as the second guiding signal. Moreover, another embodiment of the method according to the system described herein additionally or alternatively provides for the first gain factor to be constant whereas the second gain factor is different when guiding the particle beam along the second geometrical shape and when guiding the particle beam along the first geometrical shape. Alternatively, the second gain factor is constant whereas the first gain factor is different when guiding the particle beam along the second geometrical shape and when guiding the particle beam along the first geometrical shape. The aforementioned embodiments may be used in particular when the first guiding signal is used as the second guiding signal.

Another embodiment of the method according to the system described herein additionally or alternatively provides control signals used for controlling the objective lens in dependence on (i) the first distance of the center point to the first geometrical shape and on (ii) the second distance of the center point to the second geometrical shape. In particular, this embodiment of the method according to the system described herein includes providing, by the control device, a first control signal to the objective lens of the particle beam apparatus in dependence on the first distance for focusing the particle beam along the first geometrical shape. Additionally or alternatively, the method according to the system described herein includes providing, by the control device, a second control signal to the objective lens of the particle beam apparatus in dependence on the second distance for focusing the particle beam along the second geometrical shape. Additionally or alternatively, the method according to the system described herein includes (i) using an analog signal or a digital signal as the first control signal; and (ii) using an analog signal or a digital signal as the second control signal. The first control signal and/or the second control signal are/is used for further reducing or avoiding spherical aberrations. In particular, the first control signal may be used for refocusing the particle beam to the first positions. In a further embodiment of the method according to the system described herein, the first control signal in the form of a first analog signal may be used for refocusing the particle beam to the first positions. Moreover, the second control signal may be used for refocusing the particle beam to the second positions. In a further embodiment of the method according to the system described herein, the second control signal in the form of a second analog signal may be used for refocusing the particle beam to the second positions. Additionally or alternatively, the first control signal in the form of a first digital signal and/or the second control signal in the form of a second digital signal may be used to control a digital-to-analog-converter used for generating a focus signal for the objective lens of the particle beam apparatus.

An embodiment of the method according to the system described herein additionally or alternatively includes at least one of the following: (i) using the second angle as the first angle; and (ii) using the fourth angle as the third angle. Expressed differently, the first angle may be identical to the second angle. Moreover, the third angle may be identical to the fourth angle.

Another embodiment of the method according to the system described herein additionally or alternatively provides for carrying out the rocking beam method at at least one position of the first positions and/or at at least one position of the second positions. Expressed differently, at at least one position of the first positions, the first angle passes through a first predeterminable range of values and the second angle passes through a second predeterminable range of values when the particle beam is guided to the respective position of the first positions. Additionally or alternatively, at at least one position of the second positions, the third angle passes through a third predeterminable range of values and the fourth angle passes through a fourth predeterminable range of values when the particle beam is guided to the respective position of the second positions. Each of the aforementioned predeterminable ranges of values may include angles in the range of 0° to 90°, where the boundaries may be included in the aforementioned predeterminable ranges of values. A further embodiment of the method according to the system described herein additionally or alternatively provides for carrying out the rocking beam method at each position of the first positions and/or at each position of the second positions.

All of the above and following embodiments of the method according to the invention are not limited to the explained sequence of method steps. The invention also includes different sequences of the method steps which are suitable for achieving an object of the invention. Additionally or alternatively, a parallel execution of at least two method steps is also provided in the method according to the invention. Furthermore, the above and following embodiments of the method according to the invention are not limited to the entirety of all method steps mentioned above or below. In particular, it is intended that in further embodiments individual or several of the above or below mentioned method steps are omitted.

The system described herein also relates to a computer program product that includes a program code which is loadable or which is loaded into a processor of a particle beam apparatus. The program code, when executed in the processor, controls the particle beam apparatus to carry out a method having at least one of the foregoing or following features or a combination of at least two of the foregoing or following features. In other words, the system described herein also relates to a non-volatile and computer-readable medium that includes software which is loadable or is loaded into a processor of a particle beam apparatus. The software, when executed in the processor, controls the particle beam apparatus in such a way that a method having at least one of the foregoing or following features or having a combination of at least two of the foregoing or following features is carried out. The software includes executable code for performing at least one of the method steps explained herein.

Therefore, the system described herein also relates to a processor being configured to carry out a method having at least one of the foregoing or following features or a combination of at least two of the foregoing or following features.

The system described herein further relates to a particle beam apparatus for imaging, analyzing and/or processing an object, the particle beam apparatus having been explained above and being further specified below. This is briefly summarized below. The particle beam apparatus according to the system described herein includes at least one beam generator for generating a particle beam that includes charged particles. The charged particles are, for example, electrons or ions. Furthermore, the particle beam apparatus according to the system described herein includes at least one first guiding device for guiding the particle beam and at least one second guiding device for guiding the particle beam. The first guiding device may be a first deflection device, for example a first magnetic and/or electrostatic deflection device. The second guiding device may be a second deflection device, for example a second magnetic and/or electrostatic deflection device.

Moreover, the particle beam apparatus according to the system described herein includes at least one control device for providing a first guiding signal to the first guiding device and a second guiding signal to the second guiding device for guiding the particle beam. Additionally, the particle beam apparatus according to the system described herein includes at least one first signal connection being arranged between the control device and the first guiding device and at least one second signal connection being arranged between the control device and the second guiding device. The first signal connection and/or the second signal connection may be a physical connection, for example a connection line, and/or a wireless connection, for example a radio communication system and/or a wireless local area network. Additionally, the particle beam apparatus according to the system described herein includes at least one processor being arranged in or on the control device and having loaded therein a computer program product having the features mentioned herein.

In an embodiment of the particle beam apparatus according to the system described herein, the particle beam apparatus additionally or alternatively includes at least one scanning device for guiding the particle beam over the object, where the scanning device includes the first guiding device and the second guiding device.

In a further embodiment of the particle beam apparatus according to the system described herein, the particle beam apparatus additionally or alternatively includes at least one detector for detecting interaction particles and/or interaction radiation resulting from an interaction of the particle beam with the object when the particle beam impinges on the object. The interaction particles may be secondary electrons, backscattered electrons and/or secondary ions. The interaction radiation may be X-rays and/or cathodoluminescence light.

In another embodiment of the particle beam apparatus according to the system described herein, the particle beam apparatus additionally or alternatively includes at least one objective lens for focusing the particle beam onto the object. For example, the first guiding device and/or the second guiding device are/is arranged within the objective lens of the particle beam apparatus. In particular, the first guiding device and/or the second guiding device may be arranged within the objective lens along the optical axis of the particle beam apparatus. For example, the first guiding device may be configured as a first electrostatic and/or magnetic deflection device. Furthermore, the second guiding device may be configured as a second electrostatic and/or magnetic deflection device.

In a further embodiment of the particle beam apparatus according to the system described herein, the particle beam apparatus additionally or alternatively includes a first amplifier being connected to the first guiding device and a second amplifier being connected to the second guiding device.

In yet another embodiment of the particle beam apparatus according to the system described herein, it is additionally or alternatively provided that the beam genera-or is a first beam generator and that the particle beam is a first particle beam having first charged particles. The objective lens is a first objective lens for focusing the first particle beam onto the object. Furthermore, the particle beam apparatus according to the system described herein includes at least a second beam generator for generating a second particle beam with second charged particles. Furthermore, the particle beam apparatus according to the system described herein includes at least a second objective lens for focusing the second particle beam onto the object.

In particular, it is provided that the particle beam apparatus according to the system described herein is configured as an electron beam apparatus and/or as an ion beam apparatus.

### BRIEF DESCRIPTION OF DRAWINGS

Further practical embodiments and advantages of the system described herein are described below in connection with the following figures:

FIG. 1 shows a schematic representation of a first embodiment of a particle beam apparatus according to the system described herein;

FIG. 2 shows a schematic representation of a second embodiment of a particle beam apparatus according to the system described herein;

FIG. 3 shows a schematic representation of a third embodiment of a particle beam apparatus according to the system described herein;

FIG. 4 shows a schematic representation of one embodiment of a movable object stage;

FIG. 5 shows a further schematic representation of the embodiment of the movable object stage according to FIG. 4;

FIG. 6 shows a schematic representation of a sequence of a first embodiment of the method according to the system described herein;

FIG. 7 shows a schematic representation of a first geometrical shape having first positions and of a second geometrical shape having second positions;

FIG. 8 shows another schematic representation of a first geometrical shape having first positions and of a second geometrical shape having second positions;

FIG. 9 shows a schematic representation of a control device being connected to units of a particle beam apparatus; and

FIG. 10 shows a schematic representation of a sequence of a second embodiment of the method according to the system described herein.

### DETAILED DESCRIPTION OF VARIOUS EMBODIMENTS

The system described herein is explained in more detail using a particle beam apparatus in the form of an SEM and in the form of a combination apparatus that includes an electron beam column and an ion beam column. It is expressly noted that the invention can be used with any particle beam apparatus, in particular with any electron beam apparatus and/or any ion beam apparatus.

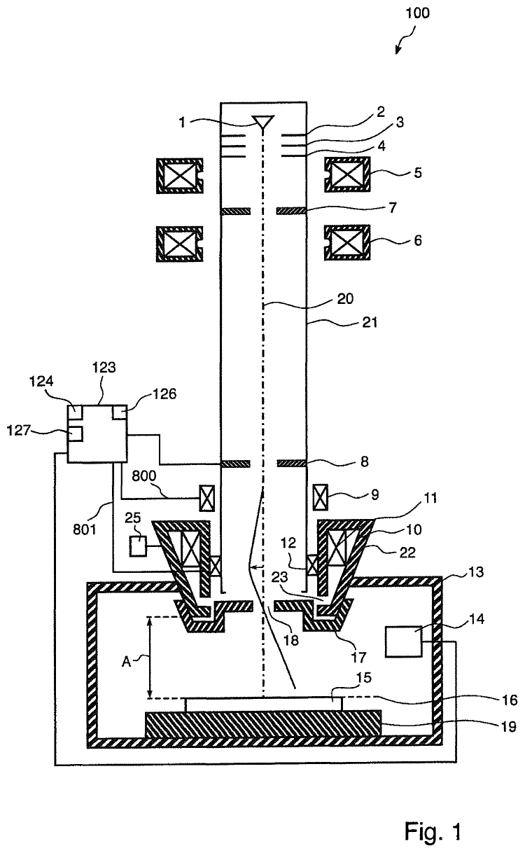

FIG. 1 shows a schematic representation of a first embodiment of a particle beam apparatus according to the system described herein in the form of an SEM 100. The SEM 100 has a beam generator 1 with an electron source, an extraction electrode 2, a control electrode 3 and an anode 4. The anode 4 forms a source-side end of a beam guiding tube 21 of the SEM 100. The beam generator 1 is configured, for example, as a thermal field emitter. Alternatively, the beam generator 1 is configured, for example, as a thermal tungsten emitter or as an LAB6 emitter.

Electrons emitted from the beam generator 1 form a primary electron beam. The electrons are accelerated to anode potential due to a potential difference between the beam generator 1 and the anode 4. For example, the potential of the anode 4 is 1 kV to 30 kV positive with respect to the potential of the beam generator 1 such that the electrons have a kinetic energy in the range between 1 keV and 30 keV.

Starting from the anode 4 and viewed in the direction of an objective lens 10 along an optical axis 20, the SEM 100 has first a first condenser lens 5 and then a second condenser lens 6. An aperture unit 7 is arranged in the beam guiding tube 21 between the first condenser lens 5 and the second condenser lens 6. In the SEM 100 shown in FIG. 1, the objective lens 10 is configured as a magnetic lens having a pole piece 22 with a pole piece gap 23. An annular coil 11 is arranged in the pole piece 22 for generating a magnetic field of the objective lens 10.

Starting from the second condenser lens 6 and viewed in the direction of the objective lens 10, a guiding device in the form of a deflection device having a first guiding device in the form of a first deflection device 9 and a second guiding device in the form of a second deflection device 12 is arranged along the optical axis 20 of the SEM 100. The first deflection device 9 is arranged on the source side of the objective lens 10. The second deflection device 12, on the other hand, is arranged on the object side inside the objective lens 10 on the beam guiding tube 21. The first deflection device 9 and the second deflection device 12 are crossed deflection devices. In other words, both the first deflection device 9 and the second deflection device 12 are configured to deflect the primary electron beam in two non-parallel directions aligned perpendicular to the direction of the optical axis 20. For example, the first deflection device 9 and/or the second deflection device 12 are/is (a) magnetic deflection device(s). In particular, the first deflection device 9 and/or the second deflection device 12 have/has, for example, four air coils arranged around the optical axis 20 of the SEM 100. Additionally or alternatively, the first deflection device 9 and/or the second deflection device 12 are/is (a) electrostatic deflection device(s). In particular, the first deflection device 9 and/or the second deflection device 12 have/has, for example, four electrodes arranged around the optical axis 20 of the SEM 100, to which different electrostatic potentials can be applied.

The objective lens 10 is arranged on an object chamber 13. In particular, the objective lens 10 projects through an opening of the object chamber 13 into an interior space of the object chamber 13. A movable object stage 19 is arranged in the interior space of the object chamber 13. An object 15 can be arranged on the object stage 19.

Using the objective lens 10, the primary electron beam generated by the beam generator 1 and formed using the first condenser lens 5 and/or the second condenser lens 6 is focused in an object plane 16. Suitable excitations of the first deflection device 9 and the second deflection device 12 ensure that the primary electron beam may be deflected in the object plane 16 perpendicular to the optical axis 20 of the SEM 100 in such a way that the surface of the object 15 arranged in the object plane 16 can be scanned by different deflections of the primary electron beam. The electrons of the primary electron beam interact with the object 15. As a result of the interaction, electrons are emitted from the object 15 (so-called secondary electrons) and electrons of the primary electron beam are scattered back (so-called backscattered electrons). The secondary electrons and the backscattered electrons are detected and are used for image generation. An image of the object 15 to be examined is thus obtained. Furthermore, interaction radiation is generated during the interaction, for example X-rays or cathodoluminescence light, which is detected and is subsequently evaluated for analysis of the object 15.

For the detection of the aforementioned interaction particles and/or aforementioned interaction radiation, for example, a first detector unit 14 is arranged in the object chamber 13. Additionally or alternatively, a second detector unit 8 for detecting the aforementioned interaction particles is arranged in the area between the first deflection device 9 and the second condenser lens 6 in the beam guiding tube 21, for example.

In the embodiment of the SEM 100 shown in FIG. 1, a pressure stage aperture holder 17 is provided which may be arranged on the pole piece 22 of the objective lens 10 projecting into the object chamber 13. The pressure stage aperture holder 17 has a pressure stage aperture with an aperture 18. Further pressure stage aperture units may be arranged, for example, within the beam guiding tube 21 of the SEM 100. The further pressure stage aperture units are not shown in FIG. 1. Vacuum pumps desired for generating and maintaining the vacuum within the beam guiding tube 21 and the object chamber 13 and desired for operation of the SEM 100 are also not shown in FIG. 1.

If the SEM 100 is operated under high vacuum in the object chamber 13, the pressure stage aperture holder 17 is not essential and accordingly may be removed from the pole piece 22 of the objective lens 10. If, on the other hand, the SEM 100 is operated at relatively high pressure in the object chamber 13 (pressures in the range of about 1 to 3000 Pa), the pressure stage aperture holder 17 may be mounted on the pole piece 22 of the objective lens 10 such that a sufficiently good vacuum may be maintained within the beam guiding tube 21 by differential pumping despite the higher pressure in the object chamber 13.

In particular, the first detector unit 14, the second detector unit 8, the first deflection device 9 and the second deflection device 12 are connected to a control device 123, which includes a monitor 124. In particular, the first deflection device 9 is connected to the control device 123 by a first signal connection 800. The first signal connection 800 may be a physical connection, for example a connection line, and/or a wireless connection, for example a radio communication system and/or a wireless local area network. The second deflection device 12 is connected to the control device 123 by a second signal connection 801. The second signal connection 801 may be a physical connection, for example a connection line, and/or a wireless connection, for example a radio communication system and/or a wireless local area network. The control device 123 processes detection signals generated by the first detector unit 14 as well as by the second detector unit 8 and displays the detection signals in the form of images on the monitor 124. The control device 123 further includes a database 126 in which data is stored and from which data is read. In addition, the control device 123 is connected to further units of the SEM 100. This is not shown further in FIG. 1.

The control device 123 of the SEM 100 includes a processor 127. A computer program product including a program code is loaded into the processor 127. The program code, when executed, carries out a method for operating the SEM 100. This is explained in more detail below.

In the SEM 100, it is possible to set a distance A using the control device 123 of the SEM 100. The distance A is given either (a) by an object distance between an outer boundary of the objective lens 10 of the SEM 100 and the object 15, or (b) by a focal plane distance between the outer boundary of the objective lens 10 of the SEM 100 and a focal plane of the objective lens 10. The aforementioned distance A according to case (a) or case (b) is also referred to as the working distance. For example, the distance A in case (a) is set by moving the object stage 19 and/or moving the objective lens 10 with a moving device 25. In particular, the distance A in case (b) is adjusted by varying an excitation of the objective lens 10 along the optical axis 20 of the SEM 100.

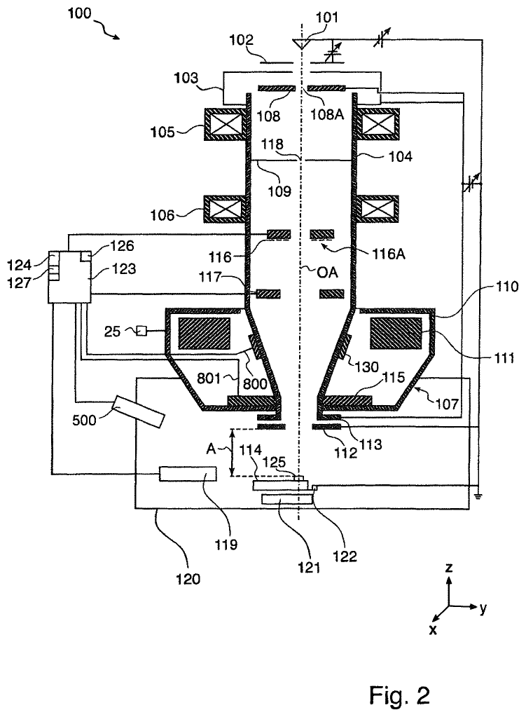

FIG. 2 shows a schematic representation of a further SEM 100. The further SEM 100 has a first beam generator in the form of an electron source 101, which is configured as a cathode. Furthermore, the further SEM 100 is provided with an extraction electrode 102 as well as with an anode 103, which is placed on one end of a beam guiding tube 104 of the further SEM 100. For example, the electron source 101 is configured as a thermal field emitter. However, the invention is not limited to such an electron source 101. Rather, any electron source suitable for the invention can be used.

Electrons emitted from the electron source 101 form a primary electron beam. The electrons are accelerated to anode potential due to a potential difference between the electron source 101 and the anode 103. In the embodiment shown in FIG. 2, the anode potential is 100 V to 35 kV with respect to a ground potential of a housing of an object chamber 120, for example 5 kV to 15 kV, in particular 8 kV. However, the anode potential could alternatively be at ground potential.

Two condenser lenses are arranged on the beam guiding tube 104, namely a first condenser lens 105 and a second condenser lens 106. Starting from the electron source 101 and viewed in the direction of a first objective lens 107, the first condenser lens 105 is arranged first, followed by the second condenser lens 106. It is explicitly noted that further embodiments of the further SEM 100 may have a single condenser lens only. A first aperture unit 108 is arranged between the anode 103 and the first condenser lens 105. Together with the anode 103 and the beam guiding tube 104, the first aperture unit 108 is at high voltage potential, namely the potential of the anode 103 or at ground. The first aperture unit 108 has numerous first apertures 108A, one of which is shown in FIG. 2. For example, there are two first apertures 108A. Each of the plurality of first apertures 108A has a different aperture diameter. Using an adjustment mechanism (not shown), it is possible to adjust a desired first aperture 108A to an optical axis OA of the further SEM 100. It is explicitly noted that the first aperture unit 108 of further embodiments may be provided with a single first aperture 108A only. In the embodiment shown in FIG. 2, an adjustment mechanism may not be provided, and the first aperture unit 108 is configured in a stationary manner. A stationary second aperture unit 109 is arranged between the first condenser lens 105 and the second condenser lens 106. Alternatively, the second aperture unit 109 may be movable.

The first objective lens 107 has pole pieces 110 having a bore. The beam guiding tube 104 is guided through the bore. A coil 111 is arranged in the pole pieces 110.

An electrostatic deceleration system is arranged in a lower region of the beam guiding tube 104. The electrostatic deceleration system has a single electrode 112 and a tubular electrode 113. The tubular electrode 113 is arranged at an end of the beam guiding tube 104 facing an object 125 being arranged at a movable object holder 114.

Together with the beam guiding tube 104, the tubular electrode 113 is at the potential of the anode 103, while the single electrode 112 and the object 125 are at a potential lower than the potential of the anode 103. In the present case, this is the ground potential of the housing of the object chamber 120. In this way, the electrons of the primary electron beam can be decelerated to a desired energy which is desired for the examination of the object 125.

The object 125 and the single electrode 112 may also be at different potentials and at different potentials than the ground potential. This makes it possible to adjust the location of the deceleration of the primary electron beam with respect to the object 125. For example, if the deceleration is performed quite close to the object 125, imaging errors become smaller.

The further SEM 100 further includes a guiding system in the form of a deflection device having a first guiding device in the form of a first deflection device 130 and having a second guiding device in the form of a second deflection device 115. The first deflection device 130 is arranged on the source side within the first objective lens 107. On the other hand, the second deflection device 115 is arranged on the object side within the first objective lens 107 on the beam guiding tube 104. The first deflection device 130 and the second deflection device 115 are crossed deflection devices. In other words, both the first deflection device 130 and the second deflection device 115 are configured to deflect the primary electron beam in two non-parallel directions aligned perpendicular to the direction of the optical axis OA of the further SEM 100. For example, the first deflection device 130 and/or the second deflection device 115 are/is (a) magnetic deflection device(s). In particular, the first deflection device 130 and/or the second deflection device 115 have/has, for example, four air coils arranged around the optical axis OA of the further SEM 100. Additionally or alternatively, it is provided that the first deflection device 130 and/or the second deflection device 115 are/is (an) electrostatic deflection device(s). In particular, the first deflection device 130 and/or the second deflection device 115 have/has, for example, four electrodes arranged around the optical axis OA of the SEM 100, to which different electrostatic potentials can be applied. Using the first deflection device 130 and the second deflection device 115, the primary electron beam is deflected and can be scanned over the object 125. The electrons of the primary electron beam interact with the object 125. As a result of the interaction, interaction particles are generated, which interaction particles are detected. In particular, electrons are emitted from the surface of the object 125 as interaction particles-so-called secondary electrons-or electrons of the primary electron beam are scattered back-so-called backscattered electrons.

A detector system is arranged in the beam guiding tube 104, which detector system includes a first detector 116 and a second detector 117 for detection of the secondary electrons and/or the backscattered electrons. The first detector 116 is arranged along the optical axis OA on the source side, while the second detector 117 is arranged along the optical axis OA on the object side in the beam guiding tube 104. The first detector 116 and the second detector 117 are offset from each other in the direction of the optical axis OA of the SEM 100. Both the first detector 116 and the second detector 117 have an opening through which the primary electron beam may pass. The first detector 116 and the second detector 117 are approximately at the potential of the anode 103 and of the beam guiding tube 104, and the optical axis OA of the SEM 100 passes through the respective opening.

The second detector 117 is primarily used for detecting secondary electrons. The secondary electrons initially have a low kinetic energy and arbitrary directions of motion as they emerge the object 125. Due to the strong extraction field emanating from the tubular electrode 113, the secondary electrons are accelerated toward the first objective lens 107. The secondary electrons enter the first objective lens 107 in an approximately parallel manner. The beam diameter of the secondary electrons remains small in the first objective lens 107. The first objective lens 107 acts strongly on the secondary electrons, generating a comparatively short focus of secondary electrons with sufficiently steep angles to the optical axis OA such that the secondary electrons travel apart after the focus and strike the second detector 117 on an active face of the second detector 117. In contrast, electrons backscattered from the object 125—i.e., backscattered electrons that have a relatively high kinetic energy as the backscattered electrons emerge from the object 125 compared to the secondary electrons—are detected by the second detector 117 only to a small extent. The high kinetic energy and the angles of the backscattered electrons with respect to the optical axis OA as the backscattered electrons emerge from the object 125 result in a beam waist, i.e., a beam region of minimum diameter, of the backscattered electrons being located in the vicinity of the second detector 117. A large portion of the backscattered electrons pass through the opening of the second detector 117. Therefore, the first detector 116 is substantially used to detect the backscattered electrons.

In another embodiment of the further SEM 100, the first detector 116 may additionally include a counter field grid 116A. The counter field grid 116A is arranged on the side of the first detector 116 facing the object 125. The counter field grid 116A has a negative potential with respect to the potential of the beam guiding tube 104 such that only backscattered electrons with a high kinetic energy pass through the counter field grid 116A to the first detector 116. Additionally or alternatively, the second detector 117 includes a further counter field grid which is designed in the same manner as the aforementioned counter field grid 116A of the first detector 116 and which has an analogous function.

Furthermore, the further SEM 100 includes a chamber detector 119 in the object chamber 120, for example an Everhart-Thornley detector or an ion detector, which may include a detection surface coated with metal that shields light.

The detection signals generated by the first detector 116, the second detector 117 and the chamber detector 119 are used to generate an image or images of the surface of the object 125.

It is explicitly noted that the apertures of the first aperture unit 108 and the second aperture unit 109 as well as the openings of the first detector 116 and the second detector 117 are shown in an exaggerated manner. The openings of the first detector 116 and the second detector 117 have an extent perpendicular to the optical axis OA in the range of 0.5 mm to 5 mm. For example, the openings are circular in shape and have a diameter in the range of 1 mm to 3 mm perpendicular to the optical axis OA.

In the embodiment shown, the second aperture unit 109 is configured as a pinhole aperture unit and is provided with a second aperture 118 for the passage of the primary electron beam. The second aperture 118 has an extension in the range from 5 μm to 500 μm, for example 35 μm. Alternatively, in a further embodiment, it is provided that the second aperture unit 109 is provided with a plurality of apertures which can be mechanically displaced with respect to the primary electron beam or which can be reached by the primary electron beam using electrical and/or magnetic deflection elements. The second aperture unit 109 may be a pressure stage aperture, which separates a first region, in which the electron source 101 is arranged and in which an ultra-high vacuum prevails (10⁻⁷ hPa to 10⁻¹² hPa), from a second region which has a high vacuum (10⁻³ hPa to 10⁻⁷ hPa). The second region is the intermediate pressure region of the beam guiding tube 104 which leads to the object chamber 120.

The object chamber 120 is under vacuum. A pump (not shown) is arranged at the object chamber 120 to generate the vacuum. In the embodiment shown in FIG. 2, the object chamber 120 is operated in a first pressure range or in a second pressure range. The first pressure range includes only pressures less than or equal to 10⁻³ hPa, and the second pressure range includes only pressures greater than 10⁻³ hPa. The object chamber 120 is vacuum sealed to ensure the first and/or the second pressure ranges.

The object holder 114 is arranged on an object stage 122. The object stage 122 is configured to be movable in three mutually perpendicular directions, namely in an x-direction (first stage axis), in a y-direction (second stage axis) and in a z-direction (third stage axis). In addition, the object stage 122 may be rotated about two mutually perpendicularly arranged rotation axes (stage rotation axes). The invention is not limited to the object stage 122 described above. Rather, the object stage 122 may have further translational axes and further rotational axes along or about which the object stage 122 may move.

The further SEM 100 further includes a third detector 121 arranged in the object chamber 120. In particular, the third detector 121 is arranged behind the object stage 122 as viewed from the electron source 101 along the optical axis OA. The object stage 122, and thus the object holder 114, may be rotated such that the primary electron beam may impinge on the object 125 being arranged on the object holder 114. As the primary electron beam passes through the object 125 to be examined, the electrons of the primary electron beam interact with the material of the object 125 to be examined. The electrons passing through the object 125 to be examined are detected by the third detector 121.

A radiation detector 500 is arranged at the object chamber 120 for detecting interaction radiation (for example X-rays and/or cathodoluminescent light) generated when the primary electron beam impinges on the object 125. The radiation detector 500, the first detector 116, the second detector 117, and the chamber detector 119 are connected to a control device 123 which includes a monitor 124. The third detector 121 is also connected to the control device 123. This is not shown for the sake of clarity. The control device 123 processes detection signals generated by the first detector 116, the second detector 117, the chamber detector 119, the third detector 121 and/or the radiation detector 500 and displays the signals in the form of images on the monitor 124.

The first deflection device 130 and the second deflection device 115 are connected to the control device 123. In particular, the first deflection device 130 is connected to the control device 123 by a first signal connection 800. The first signal connection 800 may be a physical connection, for example a connection line, and/or a wireless connection, for example a radio communication system and/or a wireless local area network. The second deflection device 115 is connected to the control device 123 by a second signal connection 801. The second signal connection 801 may be a physical connection, for example a connection line, and/or a wireless connection, for example a radio communication system and/or a wireless local area network.

The control device 123 further includes a database 126 in which data is stored and from which data is read. Furthermore, the control device 123 is connected to further units of the further SEM 100. This is not shown in more detail for reasons of clarity.

The control device 123 of the further SEM 100 includes a processor 127. A computer program product including a program code is loaded into the processor 127. When the program code is executed, a method for operating the further SEM 100 is carried out. This is explained in more detail below.

In the further SEM 100, it is possible to set a distance A using the control device 123 of the further SEM 100. The distance A is given either (a) by an object distance between the single electrode 112 of the further SEM 100 and the object 125, or (b) by a focal plane distance between the single electrode 112 of the further SEM 100 and a focal plane of the first objective lens 107. The aforementioned distance A according to case (a) or case (b) is also referred to as the working distance. For example, the distance A in case (a) is set by moving the object stage 122 and/or moving the first objective lens 107 with a moving device 25. For example, in case (b), the distance A is set by varying an excitation of the first objective lens 107 along the optical axis OA of the further SEM 100.

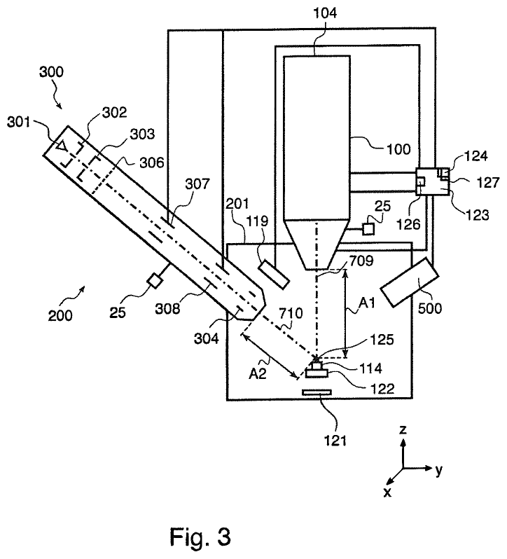

FIG. 3 shows a particle beam apparatus in the form of a combination apparatus 200. The combination apparatus 200 has two particle beam columns. On the one hand, the combination apparatus 200 has the further SEM 100 as shown in FIG. 2, but without the sample chamber 120. Rather, the further SEM 100 is arranged at an object chamber 201. The object chamber 201 is under vacuum. A pump (not shown) is arranged at the object chamber 201 to generate the vacuum. In the embodiment shown in FIG. 3, the object chamber 201 is operated in a first pressure range or in a second pressure range. The first pressure range includes only pressures less than or equal to 10⁻³ hPa, and the second pressure range includes only pressures greater than 10⁻³ hPa. The object chamber 201 is vacuum sealed to ensure the first and the second pressure ranges.

The chamber detector 119 is arranged in the object chamber 201. The chamber detector 119 is configured, for example, as an Everhart-Thornley detector or as an ion detector. The chamber detector 119 may have a detection surface coated with metal that shields light. Furthermore, the third detector 121 is arranged in the object chamber 201.

The further SEM 100 generates a first particle beam, namely the primary electron beam described above, and has the optical axis mentioned above, which optical axis is provided with the reference sign 709 in FIG. 3 and which is referred to hereinafter as the first beam axis. Secondly, the combination apparatus 200 is provided with an ion beam apparatus 300 which is also arranged at the object chamber 201. The ion beam apparatus 300 also has an optical axis which is provided with the reference sign 710 in FIG. 3 and which is referred to hereinafter as the second beam axis.

The further SEM 100 is arranged vertically with respect to the object chamber 201. In contrast, the ion beam apparatus 300 is arranged in an inclined manner to the SEM 100 by an angle of about 0° to 90°. In FIG. 3, an arrangement of about 50° is shown. The ion beam apparatus 300 includes a second beam generator in the form of an ion beam generator 301. The ion beam generator 301 is used to generate ions that form a second particle beam in the form of an ion beam. The ions are accelerated using an extraction electrode 302 which is at a predeterminable potential. The second particle beam then passes through ion optics of the ion beam apparatus 300, the ion optics including a condenser lens 303 and a second objective lens 304. Finally, the second objective lens 304 generates an ion probe that is focused on the object 125 arranged on an object holder 114. The object holder 114 is arranged on an object stage 122.

An adjustable or selectable aperture unit 306 and a guiding system are arranged above the second objective lens 304 (i.e., in the direction of the ion beam generator 301). The guiding system includes a first guiding device in the form of a first deflection device 307 and a second guiding device in the form of a second deflection device 308. The first deflection device 307 is arranged on the source side within the second objective lens 304. On the other hand, the second deflection device 308 is arranged inside the second objective lens 304 on the object side. The first deflection device 307 and the second deflection device 308 are crossed deflection devices. In other words, both the first deflection device 307 and the second deflection device 308 are configured to deflect the ion beam in two non-parallel directions aligned perpendicular to the direction of the optical axis in the form of the second beam axis 710 of the ion beam apparatus 300. For example, the first deflection device 307 and/or the second deflection device 308 are/is (a) magnetic deflection device(s). In particular, the first deflection device 307 and/or the second deflection device 308 may have, for example, four air coils arranged around the optical axis in the form of the second beam axis 710 of the ion beam apparatus 300. Additionally or alternatively, the first deflection device 307 and/or the second deflection device 308 are/is (an) electrostatic deflection device(s). In particular, the first deflection device 307 and/or the second deflection device 308 may have, for example, four electrodes arranged around the optical axis in the form of the second beam axis 710 of the ion beam apparatus 300, to which electrodes of different electrostatic potentials may be applied. Using the first deflection device 307 and the second deflection device 308, the ion beam is deflected and may be scanned over the object 125.

As explained above, the object holder 114 is arranged on the object stage 122. In the embodiment shown in FIG. 3, the object stage 122 is configured to move in three mutually perpendicular directions, namely in an x-direction (first stage axis), in a y-direction (second stage axis), and in a z-direction (third stage axis). Furthermore, the object stage 122 may be rotated about two rotation axes arranged perpendicular to each other (stage rotation axes).

The distances between the individual units of the combination apparatus 200 shown in FIG. 3 are shown in an exaggerated manner to better represent the individual units of the combination apparatus 200.

A radiation detector 500 is arranged at the object chamber 201 for detecting interaction radiation, for example X-rays and/or cathodoluminescent light. The radiation detector 500 is connected to a control device 123 which includes a monitor 124.

The control device 123 processes detection signals generated by the first detector 116 (not shown in FIG. 3), the second detector 117 (not shown in FIG. 3), the chamber detector 119, the third detector 121 and/or the radiation detector 500 and displays the signals in the form of images on the monitor 124.

The control device 123 further includes a database 126 in which data is stored and from which data is read. Further, the control device 123 is connected to the first deflection device 130 by the first signal connection 800 (not shown in FIG. 3) and to the second deflection device 115 by the second signal connection 801 (not shown in FIG. 3). Additionally, the control device 123 is connected to the first deflection device 307 by a first signal connection and to the second deflection device 308 by a second signal connection.

The control device 123 of the combination apparatus 200 includes a processor 127. A computer program product having program code is loaded into the processor 127. When executing the program code, a method for operating the combination apparatus 200 is carried out. This is explained in more detail below.

It is also possible to set working distances in the combination apparatus 200. For example, in the further SEM 100, it is possible to set a distance A1 using the control device 123. The distance A1 is given either (a) by an object distance between an outer boundary of the first objective lens 107 of the further SEM 100 and the object 125, or (b) by a focal plane distance between the outer boundary of the first objective lens 107 of the further SEM 100 and a focal plane of the first objective lens 107. The aforementioned distance A1 according to case (a) or case (b) is also referred to as the working distance. For example, the distance A1 in case (a) is set by moving the object stage 122 and/or moving the first objective lens 107 with the moving device 25. For example, in case (b), the distance A1 is adjusted by varying an excitation of the first objective lens 107 along the first beam axis 709 of the further SEM 100. Further, it is possible to adjust a distance A2 using the control device 123. The distance A2 is given by either (a) an object distance between an outer boundary of the second objective lens 304 of the ion beam apparatus 300 and the object 125, or (b) a focal plane distance between the outer boundary of the second objective lens 304 of the ion beam apparatus 300 and a focal plane of the second objective lens 304. The aforementioned distance A2 according to case (a) or case (b) is also referred to as the working distance. For example, the distance A2 in case (a) is set by moving the object stage 122 and/or moving the second objective lens 304 with a moving device 25. For example, in case (b), the distance A2 is adjusted by varying an excitation of the second objective lens 304 along the second beam axis 710 of the ion beam apparatus 300.

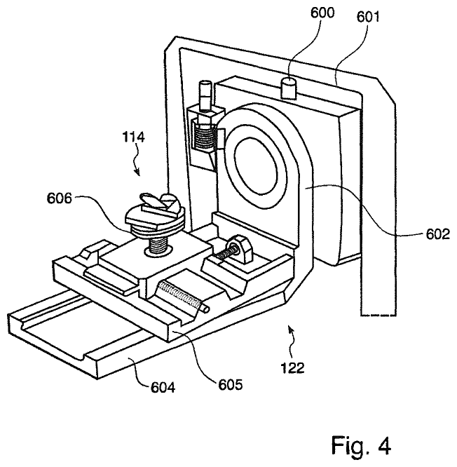

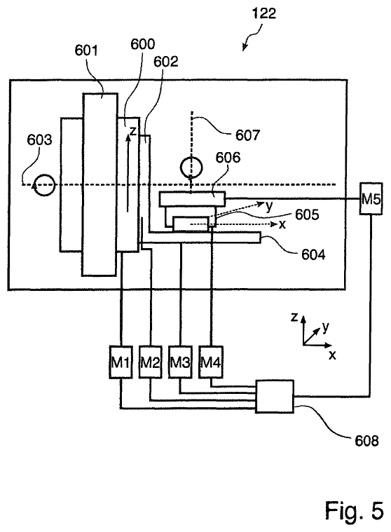

The object stage 122 of the further SEM 100 shown in FIG. 2 and of the combination apparatus 200 shown in FIG. 3 are discussed in more detail below. The object stage 122 is configured as a movable object stage which is shown schematically in FIGS. 4 and 5. The following explanation applies accordingly with regard to the object stage 19 of the SEM 100 according to FIG. 1.

It should be noted that the invention is not limited to the object stage 122 described herein. Rather, the invention may include any movable object stage suitable for the invention.

The object holder 114 is arranged on the object stage 122. The object stage 122 has motion elements that ensure movement of the object stage 122 such that an area of interest on the object 125 may be examined, for example, using a particle beam. The motion elements are shown schematically in FIGS. 4 and 5 and are explained below.

The object stage 122 has a first motion element 600 which is arranged, for example, on a housing 601 of the object chamber 120 or 201 in which the object stage 122 is arranged. The first motion element 600 enables a movement of the object stage 122 along the z-axis (third stage axis). Furthermore, a second motion element 602 is provided. The second motion element 602 enables a rotation of the object stage 122 around a first stage rotation axis 603 which is also referred to as the tilt axis. This second motion element 602 serves to tilt the object 125 about the first stage rotation axis 603, where the object 125 is arranged on the object holder 114.

A third motion element 604 is arranged on the second motion element 602 which is formed as a guide for a carriage and ensures that the object stage 122 is movable in the x-direction (first stage axis). The aforementioned carriage is in turn a further motion element, namely a fourth motion element 605. The fourth motion element 605 is configured in such a way that the object stage 122 may be moved in the y-direction (second stage axis). For this purpose, the fourth motion element 605 has a guide in which a further carriage is guided, on which the object holder 114 is arranged. The object holder 114 has a fifth motion element 606 which makes it possible to rotate the object holder 114 about a second stage rotation axis 607. The second stage rotation axis 607 is oriented perpendicular to the first stage rotation axis 603.

Based on the arrangement described above, the object stage 122 of the embodiment discussed herein has the following kinematic chain: first motion element 600 (movement along the z-axis)—second motion element 602 (rotation about the first stage rotation axis 603)—third motion element 604 (movement along the x-axis)—fourth motion element 605 (movement along the y-axis)—fifth motion element 606 (rotation about the second stage rotation axis 607).

In a further embodiment (not shown), it is intended to arrange further motion elements on the object stage 122 so that movements along further translation axes and/or about further rotational axes are made possible.

As shown in FIG. 5, each of the aforementioned motion elements is connected to a drive unit M1 to M5 in the form of a motor. The first motion element 600 is connected to a first drive unit M1 and is driven on the basis of a driving force provided by the first drive unit M1. The second motion element 602 is connected to a second drive unit M2 which drives the second motion element 602. The third motion element 604 is connected to a third drive unit M3. The third drive unit M3 provides a driving force for driving the third motion element 604. The fourth motion element 605 is connected to a fourth drive unit M4, where the fourth drive unit M4 drives the fourth motion element 605. Furthermore, the fifth motion element 606 is connected to a fifth drive unit M5. The fifth drive unit M5 provides a driving force that drives the fifth motion element 606.

The aforementioned drive units M1 to M5 can be configured as stepper motors, for example, and are controlled by a drive control unit 608. Each drive unit M1 to M5 may be supplied with a supply current by the drive control unit 608 (as shown in FIG. 5). It is explicitly noted that the invention is not limited to movement by stepper motors. Rather, any drive units which are suitable for the invention may be used as drive units, for example brushless motors.

In the following, embodiments of the method according to the system described herein are explained in more detail with respect to the SEM 100 according to FIG. 1. The method according to the system described herein may also be carried out using the further SEM 100 according to FIG. 2 and/or the combination apparatus 200 according to FIG. 3.

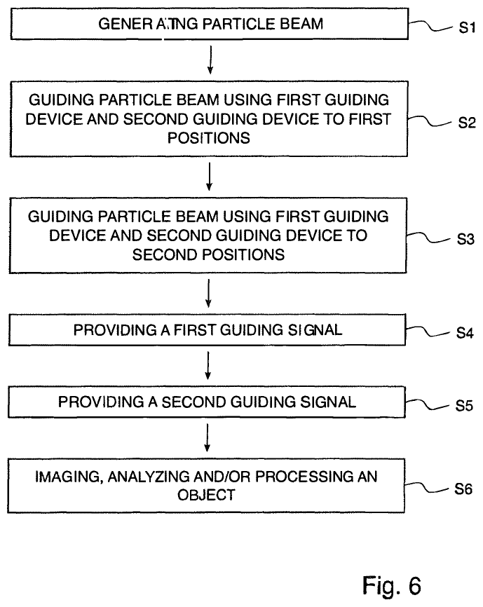

FIG. 6 shows a schematic representation of a sequence of a first embodiment of the method according to the system described herein. The method according to the system described herein is used for operating the SEM 100.

Method step S1 includes generating the primary electron beam using the beam generator 1 of the SEM 100. Method step S2 includes guiding the primary electron beam to the object 15. In particular, the primary electron beam is guided away from the optical axis 20 of the SEM 100 with a first angle with respect to the optical axis 20 using the first deflection device 9. Moreover, the primary electron beam is guided using the second deflection device 12, where the primary electron beam is guided to the optical axis 20 with a second angle with respect to the optical axis 20 in such a way that the primary electron beam is guided to first positions on a surface of the object 15. The first positions are arranged along a first geometrical shape on the surface of the object 15. The first geometrical shape may be any geometrical shape. Method step S3 includes guiding the primary electron beam to the object 15. In particular, the primary electron beam is guided away from the optical axis 20 of the SEM 100 with a third angle with respect to the optical axis 20 using the first deflection device 9. Moreover, the primary electron beam is guided using the second deflection device 12, where the primary electron beam is guided to the optical axis 20 with a fourth angle with respect to the optical axis 20 in such a way that the primary electron beam is guided to second positions on the surface of the object 15. The second positions are arranged along a second geometrical shape on the surface of the object 15. The second geometrical shape may be any geometrical shape.

Method step S4 provides a first guiding signal for guiding the primary electron beam using the control device 123 of the SEM 100. The first guiding signal is supplied to the first deflection device 9 by the control device 123 using the first signal connection 800 between the control device 123 and the first deflection device 9. As mentioned above, the first signal connection 800 may be a physical connection, for example a connection line, and/or a wireless connection, for example a radio communication system and/or a wireless local area network.

Method step S5 provides a second guiding signal for guiding the primary electron beam using the control device 123 of the SEM 100. The second guiding signal is supplied by the control device 123 to the second deflection device 12 using the second signal connection 801 between the control device 123 and the second deflection device 12. As mentioned above, the second signal connection 801 may be a physical connection, for example a connection line, and/or a wireless connection, for example a radio communication system and/or a wireless local area network.

For guiding the primary electron beam to the first geometrical shape, the first guiding signal and the second guiding signal are provided in dependence on a first distance of a center point being arranged on the surface of the object 15 to the first geometrical shape. The first guiding signal and the second guiding signal are used for guiding the primary electron beam along the first geometrical shape. The first distance may be a distance of the center point to one of the first positions being arranged on the first geometrical shape. For example, the distance may be the shortest distance of all distances of the center point to the first positions being arranged on the first geometrical shape.

For guiding the primary electron beam to the second geometrical shape, the first guiding signal and the second guiding signal are provided in dependence on a second distance of the center point being arranged on the surface of the object 15 to the second geometrical shape. The first guiding signal and the second guiding signal are used for guiding the primary electron beam along the second geometrical shape. The second distance may be a distance of the center point to one of the second positions being arranged on the second geometrical shape. For example, the distance may be the shortest distance of all distances of the center point to the second positions being arranged on the second geometrical shape.

According to the system described herein, guiding the primary electron beam along the first geometrical shape and/or along the second geometrical shape is faster in time than guiding the primary electron beam from the first geometrical shape to the second geometrical shape.

Method step S6 includes imaging, analyzing and/or processing of the object 15 using the primary electron beam at the first positions and/or at the second positions, which is referred to in the abovementioned explanations which also apply for method step S6.

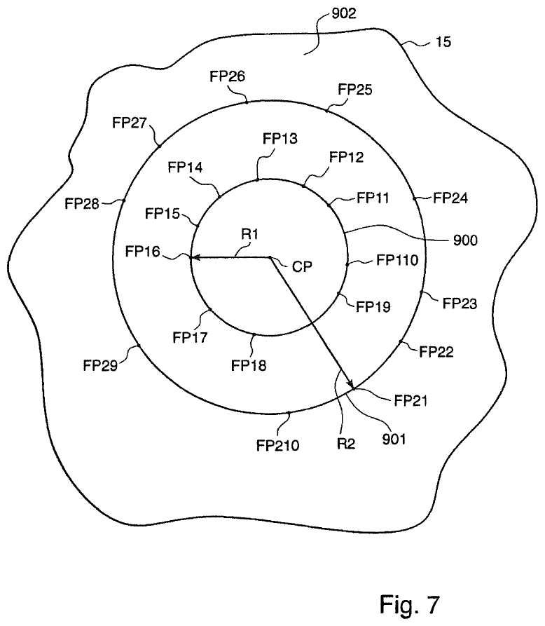

An embodiment of the method according to the system described herein uses circular shapes or full circles as the first geometrical shape and/or the second geometrical shape. FIG. 7 shows an embodiment of the first geometrical shape and the second geometrical shape. Reference sign 900 denotes the first geometrical shape in the form of a first full circle. Reference sign 901 denotes the second geometrical shape in the form of a second full circle. The first positions FP11 to FP110 are arranged along the first geometrical shape 900 on the surface 902 of the object 15. It is explicitly noted that the number of first positions being arranged along the first geometrical shape 900 is not limited to the first positions FP11 to FP110. Rather, any number of first positions may be used which is suitable for the invention. The second positions FP21 to FP210 are arranged along the second geometrical shape 901 on the surface 902 of the object 15. It is explicitly noted that the number of second positions being arranged along the second geometrical shape 901 is not limited to the second positions FP21 to FP210. Rather, any number of second positions may be used which is suitable for the invention. The first geometrical shape 900 is determined (i) by a center point CP being arranged on the surface 902 of the object 15 and (ii) by a first radius R1 extending from the center point CP along the surface 902 of the object 15. The second geometrical shape 901 is determined by the center point CP and by a second radius R2 extending from the center point CP along the surface 902 of the object 15.

With respect to the first geometrical shape 900 in the form of a first full circle, method steps S4 and S5 include providing the first guiding signal and the second guiding signal in dependence on the first radius R1 for guiding the primary electron beam along the first geometrical shape 900. With respect to the second geometrical shape 901 in the form of a second full circle, method steps S4 and S5 provide the first guiding signal and the second guiding signal in dependence on the second radius R2 for guiding the primary electron beam along the second geometrical shape 901.

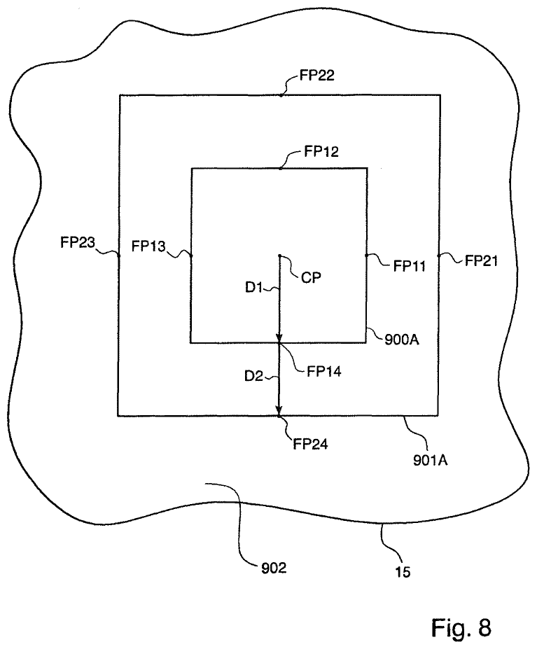

As mentioned above, the first geometrical shape 900 and the second geometrical shape 901 may be any geometrical shape. Therefore, a further embodiment of the method according to the system described herein additionally or alternatively includes (i) using a polygon as the first geometrical shape 900; and (ii) using a polygon as the second geometrical shape 901. FIG. 8 shows such an embodiment of the first geometrical shape and the second geometrical shape. Reference sign 900A denotes the first geometrical shape in the form of a first polygon, for example a square. Reference sign 901A denotes the second geometrical shape in the form of a second polygon, for example a square. The first positions FP11 to FP14 are arranged along the first geometrical shape 900A on the surface 902 of the object 15. It is explicitly noted that the number of first positions being arranged along the first geometrical shape 900A is not limited to the first positions FP11 to FP14. Rather, any number of first positions may be used which is suitable for the invention. The second positions FP21 to FP24 are arranged along the second geometrical shape 901A on the surface 902 of the object 15. It is explicitly noted that the number of second positions being arranged along the second geometrical shape 901A is not limited to the second positions FP21 to FP24. Rather, any number of second positions may be used which is suitable for the invention. The first geometrical shape 900A is determined (i) by the center point CP being arranged on the surface 902 of the object 15 and (ii) by a first distance D1 between the center point CP to one of the first positions FP11 to FP14, for example the first position FP14. The second geometrical shape 901A is determined (i) by the center point CP being arranged on the surface 902 of the object 15 and (ii) by a second distance D2 extending from the center point CP to one of the second positions FP21 to FP24, for example FP24.

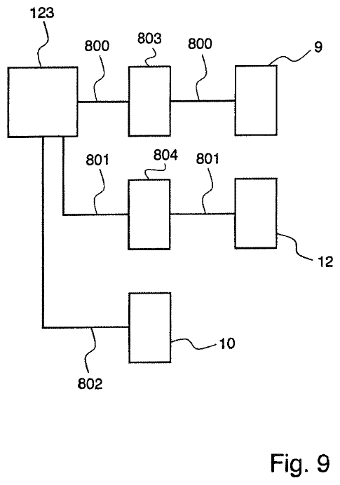

FIG. 9 shows a schematic representation of the control device 123 of the SEM 100 according to FIG. 1. The control device 123 is connected to a first amplifier 803 using the first signal connection 800. The first amplifier 803 is connected to the first deflection device 9, also using the first signal connection 800. Moreover, the control device 123 is connected to a second amplifier 804 using the second signal connection 801. The second amplifier 804 is connected to the second deflection device 12, also using the second signal connection 801. Additionally, the control device 123 is connected to the objective lens 10 using a third signal connection 802. The first signal connection 800, the second signal connection 801 and/or the third signal connection 802 may be a physical connection, for example a connection line, and/or a wireless connection, for example a radio communication system and/or a wireless local area network.

As mentioned above, the first guiding signal and the second guiding signal are provided by the control device 123. As shown in FIG. 9, the control device 123 is connected to the first amplifier 803 for providing the first guiding signal to the first deflection device 9. The first amplifier 803 is configured to increase or decrease the first guiding signal using a first gain factor. Furthermore, the control device 123 is connected to the second amplifier 804 for providing the second guiding signal to the second deflection device 12. The second amplifier 804 is configured to increase or decrease the second guiding signal using a second gain factor.

As shown, in particular, in FIG. 7, the first radius R1 is smaller than the second radius R2. The ratio of the first gain factor to the second gain factor is higher when guiding the primary electron beam along the second geometrical shape 901 than when guiding the primary electron beam along the first geometrical shape 900. The aforementioned gain factors are selected in dependence on the first radius R1 and the second radius R2.

A further embodiment of the method according to the system described herein additionally or alternatively provides for using the first guiding signal as the second guiding signal. Moreover, another embodiment of the method according to the system described herein additionally or alternatively provides for the first gain factor to be constant whereas the second gain factor is different when guiding the primary electron beam along the second geometrical shape 901 and when guiding the primary electron beam along the first geometrical shape 900. Alternatively, the second gain factor is constant whereas the first gain factor is different when guiding the primary electron beam along the second geometrical shape 901 and when guiding the primary electron beam along the first geometrical shape 900. The aforementioned embodiments may be used in particular when the first guiding signal is used as the second guiding signal.

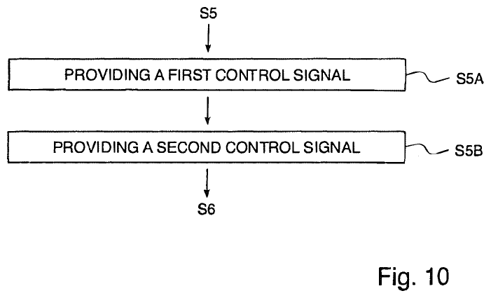

As shown in FIG. 9, the control device 123 is connected to the objective lens 10 using the third signal connection 802. A further embodiment of the method according to the system described herein may be carried out by the SEM 100 having the embodiment shown in FIG. 9. The further embodiment of the method according to the system described herein is shown in FIG. 10. The further embodiment of the method according to the system described herein shown in FIG. 10 is based on the embodiment of the method according to the system described herein shown in FIG. 6. Reference is made to the explanations given above, which also apply in connection with FIG. 10. In contrast to the embodiment according to FIG. 6, the embodiment according to FIG. 10 has additional method steps, namely method steps S5A and S5B. For example, method steps S5A and S5B are carried out after method step S5 and before method step S6. In method steps S5A and S5B control signals are provided, which control signals are used for controlling the objective lens 10 in dependence on (i) the first distance of the center point CP to the first geometrical shape 900 and on (ii) the second distance of the center point CP to the second geometrical shape 901. For example, the first distance is the first radius R1, and the second distance is the second radius R2 (see FIG. 7). Alternatively, the first distance may be the first distance D1, and the second distance may be the second distance D2 (see FIG. 8). In particular, in method step S5A, a first control signal is provided to the objective lens 10 by the control device 123, where the first control signal is dependent on the first distance. The first control signal is used for focusing the primary electron beam along the first geometrical shape 900 or 900A. Moreover, in method step S5B, a second control signal is provided to the objective lens 10 by the control device 123, where the second control signal is dependent on the second distance. The second control signal is used for focusing the primary electron beam along the second geometrical shape 901 or 901A. Furthermore, the embodiment of the method shown in FIG. 10 may include (i) using an analog signal or a digital signal as the first control signal; and (ii) using an analog signal or a digital signal as the second control signal. The first control signal and/or the second control signal are/is used for further reducing or avoiding spherical aberrations. In particular, the first control signal may be used for refocusing the primary electron beam to the first positions FP11 to FP110 (as shown in FIG. 7) or FP11 to FP14 (as shown in FIG. 8). In a further embodiment of the method shown in FIG. 10, the first control signal in the form of a first analog signal may be used for refocusing the primary electron beam to the first positions FP11 to FP110 (as shown in FIG. 7) or FP11 to FP14 (as shown in FIG. 8). Moreover, the second control signal may be used for refocusing the primary electron beam to the second positions FP21 to FP210 (as shown in FIG. 7) or FP21 to FP24 (as shown in FIG. 8). In a further embodiment of the method shown in FIG. 10, the second control signal in the form of a second analog signal may be used for refocusing the primary electron beam to the second positions FP21 to FP210 (as shown in FIG. 7) or FP21 to FP24 (as shown in FIG. 8). Additionally or alternatively, the first control signal in the form of a first digital signal and/or the second control signal in the form of a second digital signal may be used to control a digital-to-analog-converter used for generating a focus signal for the objective lens 10 of the SEM 100.

The embodiments of the method shown in FIGS. 6 and 10 may additionally include at least one of the following: (i) using the second angle as the first angle; and (ii) using the fourth angle as the third angle. Expressed differently, the first angle may be identical to the second angle. Moreover, the third angle may be identical to the fourth angle.

The embodiments of the method shown in FIGS. 6 and 10 may additionally provide for carrying out the rocking beam method at each position of the first positions FP11 to FP110 (as shown in FIG. 7) or FP11 to FP14 (as shown in FIG. 8) and/or at each position of the second positions FP21 to FP210 (as shown in FIG. 7) or FP21 to FP24 (as shown in FIG. 8). Expressed differently, at each position of the first positions FP11 to FP110 (as shown in FIG. 7) or FP11 to FP14 (as shown in FIG. 8), the first angle passes through a first predeterminable range of values and the third angle passes through a third predeterminable range of values when the primary particle beam is guided to the respective position of the first positions FP11 to FP110 (as shown in FIG. 7) or FP11 to FP14 (as shown in FIG. 8). Additionally or alternatively, the second angle passes through a second predeterminable range of values and the fourth angle passes through a fourth predeterminable range of values when the primary electron beam is guided to the respective position of the second positions FP21 to FP210 (as shown in FIG. 7) or FP21 to FP24 (as shown in FIG. 8). Each of the afore-mentioned predeterminable ranges of values may include angles in the range of 0° to 90°, where the boundaries may be included in the aforementioned predeterminable ranges of values.

All of the above and following embodiments of the method according to the invention are not limited to the explained sequence of method steps. The invention also includes different sequences of the method steps which are suitable for achieving the object of the invention. Additionally or alternatively, a parallel execution of at least two method steps is also provided in the method according to the invention.

Furthermore, the above and following embodiments of the method according to the invention are not limited to the entirety of all method steps mentioned above or below. In particular, it is intended that in further embodiments individual or several of the above or below method steps are omitted.

The features of the invention disclosed in the present description, in the drawings as well as in the claims may be essential, both individually and in any combination, for the realization of the invention in its various embodiments. The invention is not limited to the embodiments described. It may be varied within the scope of the claims and with due regard to the knowledge of the person skilled in the art.

1. A method for operating a particle beam apparatus for processing, imaging and/or analyzing an object, comprising:
generating a particle beam having charged particles using a beam generator of the particle beam apparatus;
using a first guiding device to guide the particle beam away from an optical axis of the particle beam apparatus with a first angle with respect to the optical axis;
using a second guiding device to guide the particle beam to the optical axis with a second angle with respect to the optical axis in such a way that the particle beam is guided to first positions on a surface of the object that are arranged along a first geometrical shape on the surface of the object;
guiding the particle beam using the first guiding device away from the optical axis with a third angle with respect to the optical axis;
guiding the particle beam using the second guiding device to the optical axis with a fourth angle with respect to the optical axis in such a way that the particle beam is guided to second positions on the surface of the object that are arranged along a second geometrical shape on the surface of the object;
providing a first guiding signal for guiding the particle beam using a control device and a first signal connection between the control device and the first guiding device;
providing a second guiding signal for guiding the particle beam using the control device and a second signal connection between the control device and the second guiding device;
providing the first guiding signal and the second guiding signal based on a first distance of a center point arranged on the surface of the object to the first geometrical shape to guide the particle beam along the first geometrical shape;
providing the first guiding signal and the second guiding signal based on a second distance of the center point to the second geometrical shape to guide the particle beam along the second geometrical shape, wherein guiding the particle beam along the first geometrical shape and/or along the second geometrical shape is quicker than guiding the particle beam from the first geometrical shape to the second geometrical shape.

2. The method according to claim 1, further comprising at least one of the following:
using a circular shape as the first geometrical shape;
using a circular shape as the second geometrical shape;
using a first circle as the first geometrical shape;
using a second circle as the second geometrical shape.

3. The method according to claim 2, wherein the first geometrical shape is determined by the center point and by a first radius extending from the center point along the surface of the object and wherein the second geometrical shape is determined by the center point and by a second radius extending from the center point along the surface of the object, the method further comprising:
providing the first guiding signal and the second guiding signal based on the first radius to guide the particle beam along the first geometrical shape; and
providing the first guiding signal and the second guiding signal based on the second radius to guide the particle beam along the second geometrical shape.

4. The method according to claim 1, further comprising at least one of the following:
using a polygon as the first geometrical shape;
using a polygon as the second geometrical shape.

5. The method according to claim 1, wherein the first distance is smaller than the second distance, the method further comprising:
the control device, providing the first guiding signal with a first gain factor of a first amplifier; and
the control device providing the second guiding signal with a second gain factor of a second amplifier, wherein the ratio of the first gain factor to the second gain factor is higher when guiding the particle beam along the second geometrical shape than when guiding the particle beam along the first geometrical shape.

6. The method according to claim 1, wherein the first guiding signal is used as the second guiding signal.

7. The method according to claim 1, further comprising:
the control device, providing a first control signal to an objective lens of the particle beam apparatus based on the first distance to focus the particle beam along the first geometrical shape; and
the control device providing a second control signal to the objective lens based on the second distance to focus the particle beam along the second geometrical shape.

8. The method according to claim 7, further comprising one of the following:
using an analog signal or a digital signal as the first control signal;
using an analog signal or a digital signal as the second control signal.

9. The method according to claim 1, further comprising at least one of:
using the second angle as the first angle;
using the fourth angle as the third angle.

10. A non-transitory computer readable medium containing software which is loadable into a processor and which, when executed, causes a particle beam apparatus to perform the following steps:
generating a particle beam having charged particles using a beam generator of the particle beam apparatus;
using a first guiding device to guide the particle beam away from an optical axis of the particle beam apparatus with a first angle with respect to the optical axis;
using a second guiding device to guide the particle beam to the optical axis with a second angle with respect to the optical axis in such a way that the particle beam is guided to first positions on a surface of the object that are arranged along a first geometrical shape on the surface of the object;
guiding the particle beam using the first guiding device away from the optical axis with a third angle with respect to the optical axis;
guiding the particle beam using the second guiding device to the optical axis with a fourth angle with respect to the optical axis in such a way that the particle beam is guided to second positions on the surface of the object that are arranged along a second geometrical shape on the surface of the object;
providing a first guiding signal for guiding the particle beam using a control device and a first signal connection between the control device and the first guiding device;
providing a second guiding signal for guiding the particle beam using the control device and a second signal connection between the control device and the second guiding device;
providing the first guiding signal and the second guiding signal based on a first distance of a center point arranged on the surface of the object to the first geometrical shape to guide the particle beam along the first geometrical shape; and
providing the first guiding signal and the second guiding signal based on a second distance of the center point to the second geometrical shape to guide the particle beam along the second geometrical shape, wherein guiding the particle beam along the first geometrical shape and/or along the second geometrical shape is quicker than guiding the particle beam from the first geometrical shape to the second geometrical shape.

11. A particle beam apparatus for processing, imaging and/or analyzing an object, comprising:
at least one beam generator that generates a particle beam having charged particles;
at least one first guiding device that guides the particle beam;
at least one second guiding device that guides the particle beam;
at least one control device that provides a first guiding signal and a second guiding signal for guiding the particle beam;
at least one first signal connection that is arranged between the control device and the first guiding device;
at least one second signal connection that is arranged between the control device and the second guiding device; and
a non-transitory computer readable medium containing software which is loadable into at least one processor that is arranged in or on the control device, wherein the software, when executed by the processor, causes the particle beam apparatus to perform the following steps:
generating a particle beam having charged particles using a beam generator of the particle beam apparatus;
using a first guiding device to guide the particle beam away from an optical axis of the particle beam apparatus with a first angle with respect to the optical axis;
using a second guiding device to guide the particle beam to the optical axis with a second angle with respect to the optical axis in such a way that the particle beam is guided to first positions on a surface of the object that are arranged along a first geometrical shape on the surface of the object;
guiding the particle beam using the first guiding device away from the optical axis with a third angle with respect to the optical axis;
guiding the particle beam using the second guiding device to the optical axis with a fourth angle with respect to the optical axis in such a way that the particle beam is guided to second positions on the surface of the object that are arranged along a second geometrical shape on the surface of the object;
providing a first guiding signal for guiding the particle beam using a control device and a first signal connection between the control device and the first guiding device;
providing a second guiding signal for guiding the particle beam using the control device and a second signal connection between the control device and the second guiding device;
providing the first guiding signal and the second guiding signal based on a first distance of a center point arranged on the surface of the object to the first geometrical shape to guide the particle beam along the first geometrical shape; and
providing the first guiding signal and the second guiding signal based on a second distance of the center point to the second geometrical shape to guide the particle beam along the second geometrical shape, wherein guiding the particle beam along the first geometrical shape and/or along the second geometrical shape is quicker than guiding the particle beam from the first geometrical shape to the second geometrical shape.

12. The particle beam apparatus according to claim 11, further comprising:
at least one scanning device that guides the particle beam over the object, wherein the scanning device includes the first guiding device and the second guiding device.

13. The particle beam apparatus according to claim 11, further comprising:
at least one detector unit that detects interaction particles and/or interaction radiation resulting from an interaction of the particle beam with the object.

14. The particle beam apparatus according to claim 11, further comprising:
at least one objective lens for focusing that focuses the particle beam onto the object.

15. The particle beam apparatus according to claim 14, wherein the beam generator is a first beam generator, wherein the particle beam is a first particle beam having first charged particles, wherein the objective lens is a first objective lens that focuses the first particle beam onto the object, the particle beam apparatus further comprising:
at least one second beam generator that generates a second particle beam comprising second charged particles; and
at least a second objective lens that focuses the second particle beam onto the object.

16. The particle beam apparatus according to claim 11, further comprising:
a first amplifier that is connected to the first guiding device and a second amplifier that is connected to the second guiding device.

17. The particle beam apparatus according to claim 11, wherein the particle beam apparatus is an electron beam apparatus and/or an ion beam apparatus.
